(19) United States
(12) Patent Application Publication
(10) Pub. No.: US 2023/0183849 A1
(43) Pub. Date: Jun. 15, 2023

(54) METHOD OF FORMING SILICIDE FILM

(71) Applicant: SUMITOMO HEAVY INDUSTRIES, LTD., Tokyo (JP)

(72) Inventor: Taku OBA, Yokosuka-shi (JP)

(21) Appl. No.: 18/066,042

(22) Filed: Dec. 14, 2022

(30) Foreign Application Priority Data
Dec. 15, 2021 (JP) 2021-203302

(51) Int. Cl. C23C 14/00; C23C 14/16; C23C 14/58

(52) U.S. Cl. CPC C23C 14/0036; C23C 14/16; C23C 14/5813

(57) ABSTRACT

A method of forming a silicide film including: disposing a semiconductor wafer containing silicon as a constituent element in a sputtering chamber; evacuating an inside of the sputtering chamber until a pressure reaches 9×10⁻⁵ Pa or less; introducing a sputtering gas into the sputtering chamber and sputtering a target in the sputtering chamber to deposit a metal film on the semiconductor wafer; and causing a laser beam to be incident into the metal film deposited on the semiconductor wafer to form a metal silicide film by a silicide reaction.

### CROSS-REFERENCE TO RELATED APPLICATIONS

This application claims priority to Japanese Patent Application No. 2021-203302, filed on Dec. 15, 2021, which is incorporated by reference herein in its entirety.

### BACKGROUND

### Technical Field

A certain embodiment of the present invention relates to a method of forming a silicide film.

### Description of Related Art

A technique for forming a metal silicide film by depositing a metal film on a silicon-containing semiconductor wafer such as a silicon wafer or a silicon carbide (SiC) wafer and performing laser annealing thereon is known (related art). As the metal film, Ni, Ti, Mo, W, or the like is used.

### SUMMARY

According to an aspect of the present invention, there is provided a method of forming a silicide film including: disposing a semiconductor wafer containing silicon as a constituent element in a sputtering chamber; evacuating an inside of the sputtering chamber until a pressure reaches 9×10⁻⁵ Pa or less; introducing a sputtering gas into the sputtering chamber and sputtering a target in the sputtering chamber to deposit a metal film on the semiconductor wafer; and causing a laser beam to be incident into the metal film deposited on the semiconductor wafer to form a metal silicide film by a silicide reaction.

### BRIEF DESCRIPTION OF THE DRAWINGS

FIG. 1 is a flowchart showing a procedure of a method of forming a silicide film according to an embodiment.

FIGS. 2A to 2C are cross-sectional views of a wafer in an intermediate stage until a metal silicide film is formed, and FIG. 2D is a cross-sectional view of the wafer on which the metal silicide film is formed.

FIG. 3 is a schematic view of a laser annealing apparatus used in the present embodiment.

FIGS. 4A and 4B are optical micrographs of metal silicide films produced by methods according to the embodiment and a comparative example, respectively.

FIGS. 5A and 5B are schematic views showing cross sections of metal film laminated wafers produced by the methods according to the embodiment and the comparative example, respectively.

### DETAILED DESCRIPTION

It is desired to form a uniform metal silicide film on the entire surface of a semiconductor wafer. According to various evaluation experiments by the inventor of the present application, it has been confirmed that unevenness in appearance may occur in a metal silicide film formed by laser annealing. According to an embodiment of the present invention, it is desirable to provide a method of forming a silicide film capable of forming a uniform metal silicide film on a semiconductor wafer.

By evacuating the inside of the sputtering chamber until the pressure reaches 9×10⁻⁵ Pa or less before introducing the sputtering gas, the amount of oxygen atoms incorporated into the metal film is reduced. As a result, it is possible to suppress the occurrence of unevenness in appearance of the metal silicide film.

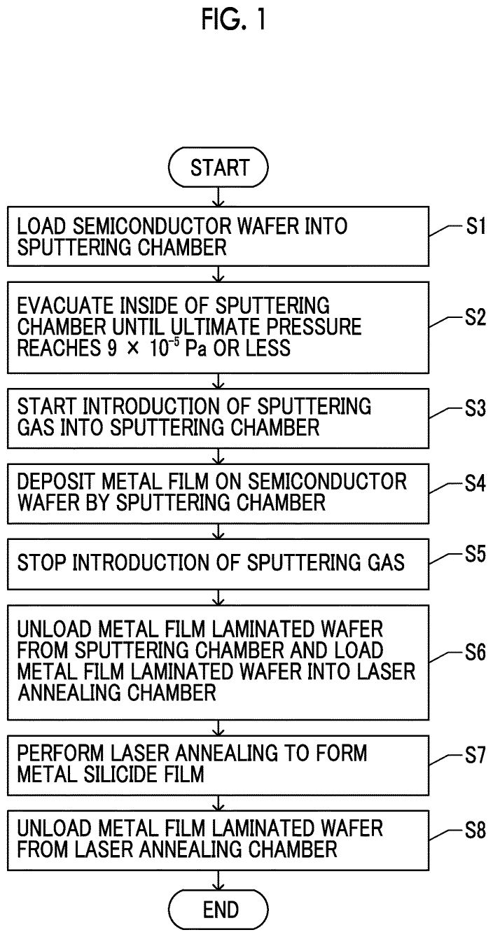

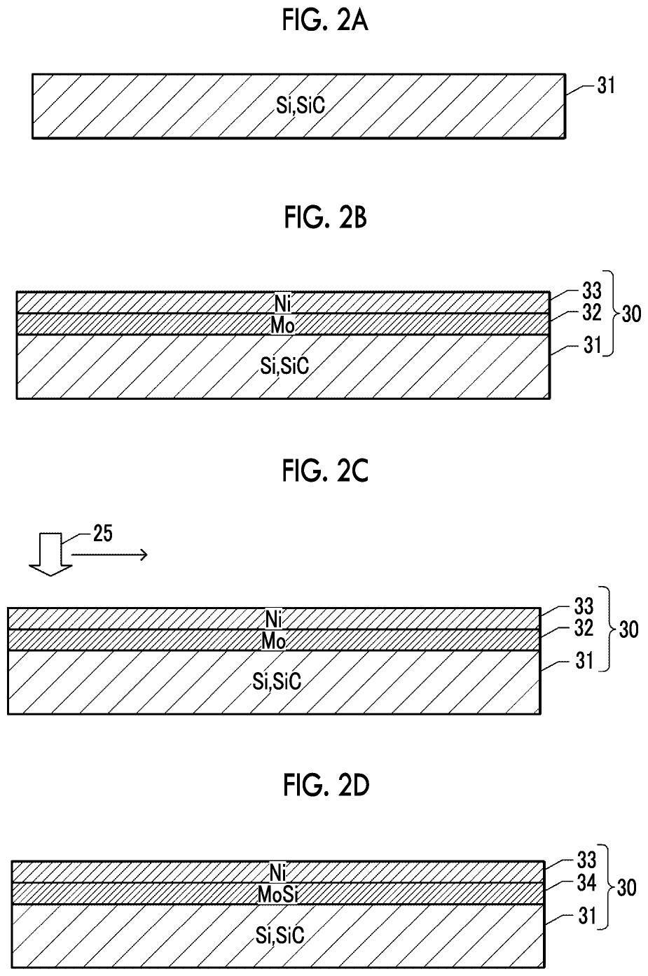

A method of forming a silicide film according to an embodiment will be described with reference to FIGS. 1 to 5B. FIG. 1 is a flowchart showing a procedure of the method of forming a silicide film according to the present embodiment. FIGS. 2A to 2C are cross-sectional views of a wafer in an intermediate stage until a metal silicide film is formed, and FIG. 2D is a cross-sectional view of the wafer on which the metal silicide film is formed.

First, a semiconductor wafer 31 (FIG. 2A) is loaded into a sputtering chamber of a sputtering apparatus (step S1). The semiconductor wafer 31 is formed of a semiconductor containing silicon. For example, the semiconductor wafer 31 is a silicon wafer or a SiC wafer. As the sputtering apparatus, for example, an RF magnetron sputtering apparatus is used. As a target for sputtering, metal molybdenum (Mo) is used.

After the semiconductor wafer 31 is loaded, an inside of the sputtering chamber is evacuated (step S2). A pressure of the sputtering chamber at this time is set to 9×10⁻⁵ Pa. A pressure corresponding to the degree of vacuum in the sputtering chamber before the introduction of a sputtering gas is referred to as an ultimate pressure Pm. After evacuating the inside of the sputtering chamber, introduction of the sputtering gas is started (step S3). Furthermore, a molybdenum film 32 (FIG. 2B) is deposited on the semiconductor wafer 31 by starting discharging in the sputtering chamber to perform sputtering, and the target is changed to deposit a nickel film 33 (FIG. 2B) on the molybdenum film 32 (step S4). The wafer including the semiconductor wafer 31, the molybdenum film 32, and the nickel film 33 is referred to as a metal film laminated wafer 30.

After depositing the nickel film 33, the introduction of the sputtering gas is stopped (step S5). Thereafter, the metal film laminated wafer 30 is unloaded from the sputtering chamber and is loaded into an annealing chamber (step S6).

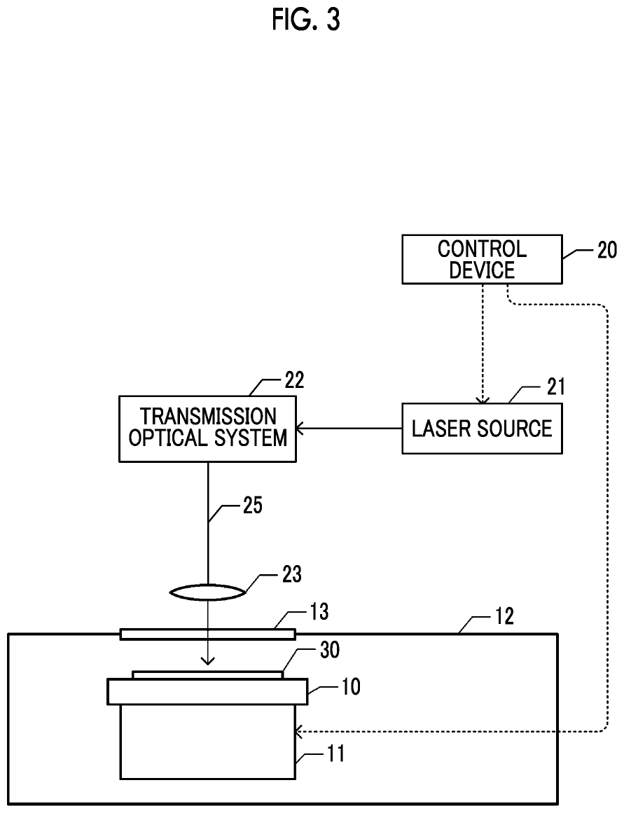

FIG. 3 is a schematic view of a laser annealing apparatus used in the present embodiment. A stage 10 is supported by a moving mechanism 11 in an annealing chamber 12. The moving mechanism 11 can move the stage 10 in a horizontal plane in response to a command from a control device 20. The metal film laminated wafer 30 (FIG. 2B) in which the molybdenum film 32 and the nickel film 33 are formed is held on an upper surface of the stage 10 with the nickel film 33 facing upward.

A laser source 21 receives a command from the control device 20 and outputs a pulsed laser beam for annealing. As the laser source 21, for example, a laser diode having an oscillation wavelength of about 800 nm is used. A pulsed laser beam 25 output from the laser source 21 passes through a transmission optical system 22 and a lens 23, is transmitted by a laser transmission window 13 provided on a top plate of the annealing chamber 12, and is incident into the metal film laminated wafer 30. The transmission optical system 22 includes, for example, a beam homogenizer, an aperture, a lens, and a mirror. A beam spot on a surface of the metal film laminated wafer 30 is shaped by the beam homogenizer and the lens 23, such that a beam profile is uniformized.

The control device 20 controls the moving mechanism 11 to move the stage 10 in a two-dimensional direction in the horizontal plane. The control device 20 further controls the laser source 21 to output the pulsed laser beam 25 from the laser source 21 based on current position information of the stage 10. For example, the control device 20 controls the moving mechanism 11 and the laser source 21 to move the beam spot of the pulsed laser beam 25 (FIG. 2C) on the surface of the metal film laminated wafer 30 in a main scanning direction and a sub-scanning direction. By repeating main scanning and sub-scanning, almost the entire surface of the metal film laminated wafer 30 can be annealed.

After step S6, laser annealing is performed on the metal film laminated wafer 30 to cause a silicide reaction to occur between the silicon contained in the semiconductor wafer 31 and the molybdenum film 32, thereby forming a molybdenum silicide film 34 (FIG. 2D) (step S7). The notation “MoSi” shown in FIG. 2D does not mean that a composition ratio between Mo and Si is 1:1. When the laser annealing is ended, the metal film laminated wafer 30 is unloaded from the annealing chamber 12 (FIG. 3) (step S8).

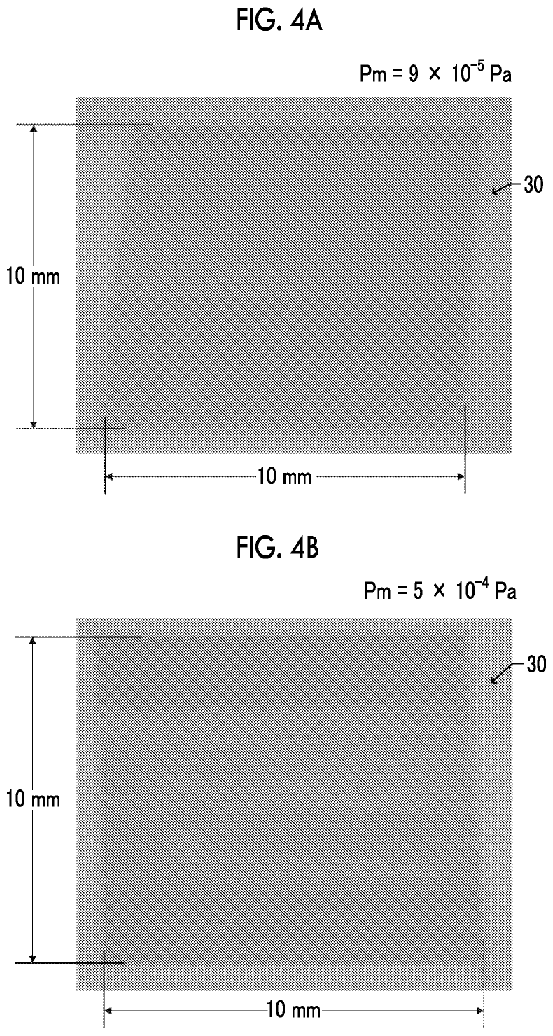

Next, excellent effects of the embodiment will be described with reference to FIGS. 4A and 4B. FIGS. 4A and 4B are optical micrographs of metal silicide films produced by methods according to the embodiment and a comparative example, respectively. A slightly dark region in FIGS. 4A and 4B is the metal film laminated wafer 30. A shape of the metal film laminated wafer 30 is a square having a side length of 10 mm. In the comparative example shown in FIG. 4B, the ultimate pressure Pm in step S2 (FIG. 1) is set to 5×10⁻⁴ Pa.

In the method according to the embodiment, as shown in FIG. 4A, a uniform metal silicide film is formed in appearance. On the other hand, in the method according to the comparative example, it can be seen that color unevenness (a dark gray region and a light gray region in the photograph) occurs in appearance.

As described above, by applying the method according to the embodiment, it is possible to form the molybdenum silicide film 34 (FIG. 2D) that is uniform without color unevenness in appearance.

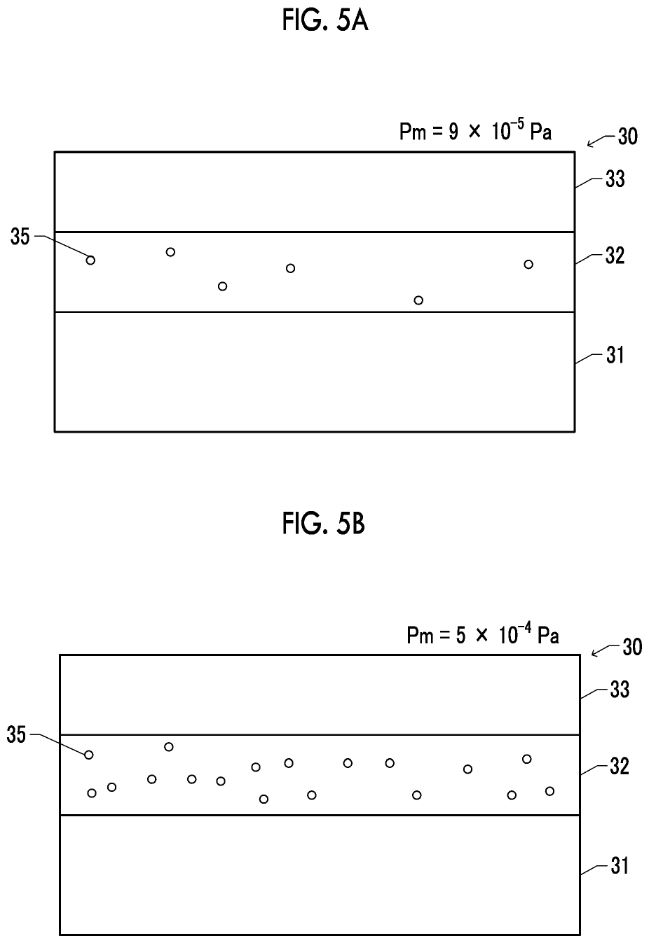

Next, a cause of unevenness in appearance on the molybdenum silicide film produced by the method according to the comparative example will be described with reference to FIGS. 5A and 5B.

FIGS. 5A and 5B are schematic views showing cross sections of the metal film laminated wafers 30 produced by the methods according to the embodiment and the comparative example, respectively. The molybdenum film 32 is formed on the semiconductor wafer 31, and the nickel film 33 is formed thereon. When the molybdenum film 32 is deposited by sputtering, oxygen atoms 35 are incorporated into the molybdenum film 32. According to an evaluation experiment by the inventor of the present application, it has been found that when the ultimate pressure Pm in step S2 is high (the degree of vacuum is low), the amount of oxygen atoms 35 incorporated into the molybdenum film 32 increases. In the embodiment (FIG. 5A), the ultimate pressure Pm is set to 9×10⁻⁵ Pa, and in the comparative example (FIG. 5B), the ultimate pressure Pm is set to 5×10⁻⁴ Pa. Therefore, the amount of oxygen incorporated into the molybdenum film 32 (FIG. 5B) produced by the method according to the comparative example is larger than the amount of oxygen incorporated into the molybdenum film 32 (FIG. 5A) produced by the method according to the embodiment.

The oxygen atoms 35 incorporated into the molybdenum film 32 reacts with molybdenum during the laser annealing (step S7). Due to an oxidation reaction of molybdenum during the laser annealing, color unevenness in appearance occurs on the molybdenum silicide film 34 (FIG. 2D). By setting the ultimate pressure Pm in step S2 to 9×10⁻⁵ Pa or less, the molybdenum silicide film 34 (FIG. 2D) that is uniform without color unevenness in appearance can be formed.

Next, a modification example of the embodiment will be described. In the embodiment, the nickel film 33 (FIG. 2B) is deposited on the molybdenum film 32 (FIG. 2B), but the nickel film 33 can be omitted. In this case, the pulsed laser beam 25 (FIG. 2C) for annealing is incident into the metal film laminated wafer 30 in which the molybdenum film 32 is exposed, thereby causing a silicide reaction.

In addition, although the metal film is deposited by using the RF magnetron sputtering method in the embodiment, other sputtering methods may also be used. For example, a DC magnetron sputtering method may be used.

In addition, in the embodiment, the molybdenum film 32 (FIG. 2C) is used as the metal film that causes the silicide reaction. However, a film made of a metal other than molybdenum that causes the silicide reaction may also be used. Examples of such a metal include nickel, titanium, and tungsten. Even in a case where a metal film other than the molybdenum film is used as the metal film that causes the silicide reaction, when a large amount of oxygen is incorporated into the metal film, an oxidation reaction of the metal occurs during the laser annealing, which may cause color unevenness in appearance. Therefore, even in a case where a metal film other than the molybdenum film is used as the metal film that causes the silicide reaction, it is preferable to perform evacuation until the ultimate pressure Pm in step S2 reaches 9×10⁻⁵ Pa or less.

Furthermore, in order to avoid an increase in the amount of oxygen incorporated into the metal film that causes the silicide reaction with silicon, a purity of argon gas used as the sputtering gas is preferably set to 99.9995% or higher.

It is needless to say that the embodiment is an example, and partial substitutions or combinations of the configurations shown in the embodiment and the modification examples can be made. The same actions and effects due to the same configurations of the embodiment and the modification examples are not sequentially mentioned for each of the embodiment and the modification examples. Furthermore, the present invention is not limited to the embodiment and the modification examples. For example, it is obvious to those skilled in the art that various changes, improvements, combinations, and the like can be made.

It should be understood that the invention is not limited to the above-described embodiment, but may be modified into various forms on the basis of the spirit of the invention. Additionally, the modifications are included in the scope of the invention.

What is claimed is:

1. A method of forming a silicide film comprising:
disposing a semiconductor wafer containing silicon as a constituent element in a sputtering chamber;
evacuating an inside of the sputtering chamber until a pressure reaches 9×10⁻⁵ Pa or less;
introducing a sputtering gas into the sputtering chamber and sputtering a target in the sputtering chamber to deposit a metal film on the semiconductor wafer; and
causing a laser beam to be incident into the metal film deposited on the semiconductor wafer to form a metal silicide film by a silicide reaction.

2. The method of forming a silicide film according to claim 1, wherein the sputtering gas is an argon gas having a purity of 99.9995% or higher.
